(19) United States
(12) Patent Application Publication
(10) Pub. No.: US 2026/0298416 A1
(43) Pub. Date: Oct. 1, 2026

(54) FLUID DISTRIBUTION DEVICE

(71) Applicant: Process Technology, LLC, Willoughby, OH (US)

(72) Inventor: David BARNHART, Jefferson, OH (US)

(73) Assignee: Process Technology, LLC, Willoughby, OH (US)

(21) Appl. No.: 19/630,861

(22) Filed: Mar. 27, 2026

Related U.S. Application Data
(60) Provisional application No. 63/780,651, filed on Mar. 31, 2025.

(51) Int. Cl. F17D 1/08

(52) U.S. Cl. CPC F17D 1/08

(57) ABSTRACT

A fluid distribution device includes a manifold, a plurality of tubes, a plurality of fittings, and a support block. The manifold includes a plurality of recessed outlet ports which include a primary hole, a threaded secondary hole, and a sleeve having a bulbous region. Each tube of the plurality of tubes includes a tube bulbous region at a first end thereof configured to mate with the sleeve bulbous region. Each fitting of the plurality of fittings is configured to connect a tube of the plurality of tubes to a recessed outlet port of the plurality of recessed outlet ports by mating a threaded outer surface of the fitting to the threaded secondary hole. The support block includes an upper section and a lower section, each having a plurality of grooves configured to a longitudinal portion of an exterior profile of the tubes and fittings. A plurality of fasteners connects the upper section to the lower section, and an attachment mechanism connects the support block to the manifold sidewall outer surface which in turn is attached to the casing.

### CROSS REFERENCES AND PRIORITIES

This Application claims priority from U.S. Provisional Application No. 63/780,651 filed on Mar. 31, 2025, the teachings of which are incorporated by reference herein in their entirety.

### BACKGROUND

Fluid distribution devices are used in a number of manufacturing processes for a number of purposes. For example, in semiconductor manufacturing processes, fluid—often in the form of liquid isopropyl alcohol (IPA)—is frequently used for dewatering, drying, and removing impurities.

Existing fluid distribution devices used in semiconductor manufacturing typically include a manifold having an inlet port and a plurality of outlet ports. Fluid—such as IPA—is introduced into the manifold via the inlet port, flows through the manifold, and exits through the outlet ports to a plurality of tubes to be distributed to various locations in the manufacturing process. Typically, the tubes will be connected to the outlet ports by one or more fittings. A support block is often connected to the manifold to hold the tubes in place and guard against loosening of the fittings. The components of the fluid distribution device may be manufactured of a metal material such as aluminum (often coated with nickel) and/or a plastic material such as polytetrafluoroethylene (PTFE) or polyether ether ketone (PEEK)—often reinforced with fibers such as glass fibers—which offers improved resistance to corrosion over time caused by fluids such as IPA.

In practice, existing fluid distribution devices—particularly those used for distributing IPA—have been found unreliable. Leakage frequently occurs over time at various points in the device including at the manifold, at one or more of the fittings, and along one or more of the tubes. This leakage can lead to undesirable contamination to the manufacturing process, often requiring extended down time to repair or replace the fluid distribution device.

The need exists, therefore, for an improved fluid distribution device which reduces or eliminates leakage.

### SUMMARY

A fluid distribution device includes a manifold, a plurality of tubes, a plurality of fittings, and a support block. The manifold including an intake port, an interior space downstream of the intake port, and a plurality of recessed outlet ports downstream of the interior space. Each recessed outlet port of the plurality of recessed outlet ports including a primary hole, a threaded secondary hole, and a sleeve. The primary hole extending through a manifold sidewall and having a primary hole diameter. The threaded secondary hole originating from a manifold sidewall outer surface, having a depth which is less than a manifold sidewall thickness, having a secondary hole diameter which is greater than the primary hole diameter, and having a secondary hole lip. The sleeve extending from the secondary hole lip and having a sleeve bulbous region. Each tube of the plurality of tubes having a first end with a tube bulbous region configured to mate with the sleeve bulbous region. Each fitting of the plurality of fittings configured to connect a tube of the plurality of tubes to a recessed outlet port of the plurality of recessed outlet ports. Each fitting of the plurality of fitting having a fitting sidewall, a through hole extending from a fitting first end through a fitting second end, and a threaded outer surface originating from the fitting first end and terminating before the fitting second end with the threaded outer surface configured to mate with the threaded secondary hole. The support block including an upper section, a lower section, at least one fastener, and an attachment mechanism. The upper section having an upper section outer surface, an upper section inner surface opposite the upper section outer surface, and a plurality of upper section grooves in the upper section inner surface. Each upper section groove of the plurality of upper section grooves being configured to a first longitudinal portion of an exterior profile of one tube and one fitting of the plurality of tubes and fittings. The lower section having a lower section outer surface, a lower section inner surface opposite the lower section outer surface, and a plurality of lower section grooves in the lower section inner surface. Each lower section groove of the plurality of lower section grooves being configured to a second longitudinal portion of an exterior profile of one tube and one fitting of the plurality of tubes and the plurality of fittings. The at least one fastener being configured to securely connect the upper section to the lower section. The attachment mechanism being configured to connect the support block to the manifold sidewall outer surface.

In some embodiments, the plurality of recessed outlet ports may include a number of recessed outlet ports which is an integer in the range of between 2 and 10. In certain embodiments, the plurality of tubes may include a number of tubes which is an integer in the range of between 2 and 10. In such embodiments, the number of recessed outlet ports may equal the number of tubes. In some embodiments, the plurality of fittings may include a number of fittings which is an integer in the range of between 2 and 10. In such embodiments, the number of tube may equal the number of fittings.

In certain embodiments, the upper section may include a plurality of upper section through holes extending from the upper section outer surface through the upper section inner surface. In some such embodiments, the lower section may include a plurality of lower section holes extending into the lower section inner surface. In such embodiments, the fastener may include a plurality of bolts with each bolt configured to securely connect the upper section to the lower section by passing through one upper section through hole of the plurality of upper section through holes and threading into one lower section hole of the plurality of lower section holes.

In some embodiments, the attachment mechanism may include a first lip and a second lip. The first lip may extend along at least a portion of a manifold sidewall upper edge and may be configured to mate with a first tab extending from an upper section proximal edge. The second lip may extend along at least a portion of a manifold sidewall lower edge and may be configured to mate with a second tab extending from a lower section proximal edge.

In certain embodiments, each tube of the plurality of tubes may have a sidewall thickness in a range of between 0.035 cm and 0.065 cm. In some embodiments, each tube of the plurality of tubes may be manufactured of a conductive material having a volume resistivity in a range of between 2.0×10² Ω. cm. In certain embodiments, each tube of the plurality of tubes may be manufactured of a conductive material having a surface resistivity in a range of between 10Ω/sq and 10⁶ Ω/sq. In some embodiments, each tube of the plurality of tubes may be manufacture of perfluoroalkoxy alkane (PFA).

In certain embodiments, the fluid distribution device may be void of o-rings in a fluid path extending between the intake port and each tube of the plurality of tubes.

In some embodiments, the manifold, the plurality of tubes, and the plurality of fittings may each be manufactured of a polymer material. In certain such embodiments, the polymer material may be selected from the group consisting of polytetrafluoroethylene (PTFE), perfluoroalkoxy alkane (PFA), and polyvinylidene fluoride (PVDF). In some such embodiments, the polymer material may be reinforced with glass fibers. In certain such embodiments, the polymer material maybe coated with a material selected from the group consisting of polyvinylidene fluoride (PVDF), ethylene chlorotrifluoroethylene (ECTFE), perfluoroalkoxy alkane (PFA), fluorinated ethylene propylene (FEP), ethylene tetrafluoroethylene (ETFE), and nickel polytetrafluoroethylene (Ni-PTFE).

In certain embodiments, the support block may be manufactured of a material selected from the group consisting of a metal material and a polymer material. When the support block is manufactured of a polymer material, the polymer material may be polyether ether ketone (PEEK). In some embodiments, the polymer material may be reinforced with glass fibers. In certain such embodiments, the polymer material maybe coated with a material selected from the group consisting of polyvinylidene fluoride (PVDF), ethylene chlorotrifluoroethylene (ECTFE), perfluoroalkoxy alkane (PFA), fluorinated ethylene propylene (FEP), ethylene tetrafluoroethylene (ETFE), and nickel polytetrafluoroethylene (Ni-PTFE).

### BRIEF DESCRIPTION OF FIGURES

FIG. 1 illustrates an exploded perspective view of an embodiment of a fluid distribution device manifold and support block.

FIG. 2 illustrates an assembled perspective view of an embodiment of a fluid distribution device.

FIG. 3 illustrates a side cross section view of an embodiment of a manifold for a fluid distribution device.

FIG. 4 illustrates an end cross section view of an embodiment of a manifold for a fluid distribution device.

FIG. 5 illustrates an exploded end cross section view of an embodiment of a manifold, fitting, and tube for a fluid distribution device.

FIG. 6A illustrates an exploded lower perspective view of an embodiment of a support block for a fluid distribution device.

FIG. 6B illustrates an exploded upper perspective view of an embodiment of a support block for a fluid distribution device.

FIG. 7 illustrates an end cross section view of an embodiment of a fluid distribution device.

### DETAILED DESCRIPTION

Disclosed herein is a fluid distribution device. As described herein, the following numbers refer to the following structures as noted in the Figures.
10 refers to a fluid distribution device.
100 refers to a manifold.
110 refers to an intake port.
120 refers to an interior space.
130 refers to a recessed outlet port.
131 refers to a primary hole.
132 refers to a primary hole diameter.
133 refers to a threaded secondary hole.
134 refers to a secondary hole diameter.
135 refers to a secondary hole lip.
136 refers to a sleeve.
137 refers to a sleeve bulbous region.
140 refers to a manifold sidewall.
141 refers to a manifold sidewall outer surface.
142 refers to a manifold sidewall thickness.
143 refers to a manifold sidewall upper edge.
144 refers to a manifold sidewall lower edge.
200 refers to a tube.
210 refers to a first end (of a tube).
215 refers to a tube bulbous region.
300 refers to a fitting.
310 refers to a fitting sidewall.
311 refers to a fitting first end.
312 refers to a fitting second end.
315 refers to a threaded outer surface.
320 refers to a through hole.
400 refers to a support block.
410 refers to an upper section (of a support block).
411 refers to an upper section outer surface.
412 refers to an upper section inner surface.
413 refers to an upper section through hole.
414 refers to an upper section groove.
415 refers to an upper section proximal edge.
420 refers to a lower section (of a support block).
421 refers to a lower section outer surface.
422 refers to a lower section inner surface.
423 refers to a lower section hole.
424 refers to a lower section groove.
425 refers to a lower section proximal edge.
430 refers to a fastener.
440 refers to an attachment mechanism.
441 refers to a first lip.
442 refers to a first tab.
443 refers to a second lip.
444 refers to a second tab.

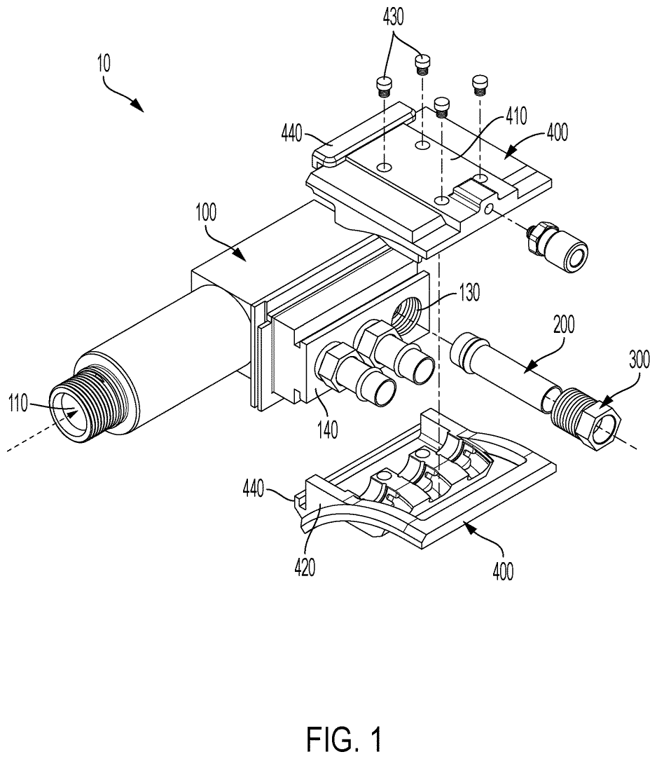

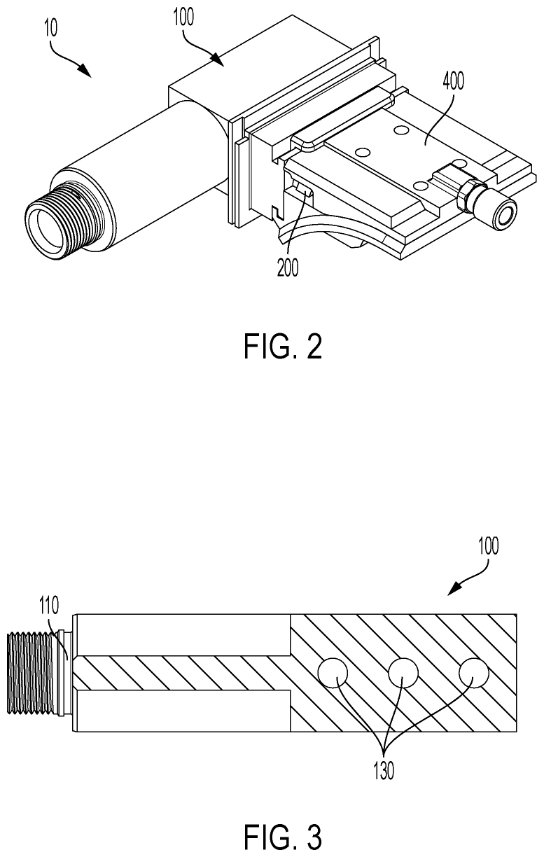

FIG. 1 illustrates an exemplary embodiment of a fluid distribution device (10) in exploded perspective view with FIG. 2 illustrating the exemplary embodiment of a fluid distribution device in assembled perspective view. As shown in FIGS. 1 and 2, the fluid distribution device includes a manifold (100), a plurality of tubes (200), a plurality of fittings (300), and a support block (400) comprising an upper section (410) and a lower section (420). Fluid—which is preferably in a liquid state, but may also be in a gaseous state—enters the manifold through an intake port (110) and is discharged from the manifold into the plurality of tubes through a plurality of recessed outlet ports (130) in a manifold sidewall (140) and then wound onto a heated core. Each tube of the plurality of tubes being connected to a recessed outlet port of the plurality of recessed outlet ports via a fitting of the plurality of fittings. Preferably, the fluid distribution device will be void of structures such as o-rings which are not considered to be of high purity for the manufacturing process in the fluid path extending between the intake port and each tube of the plurality of tubes.

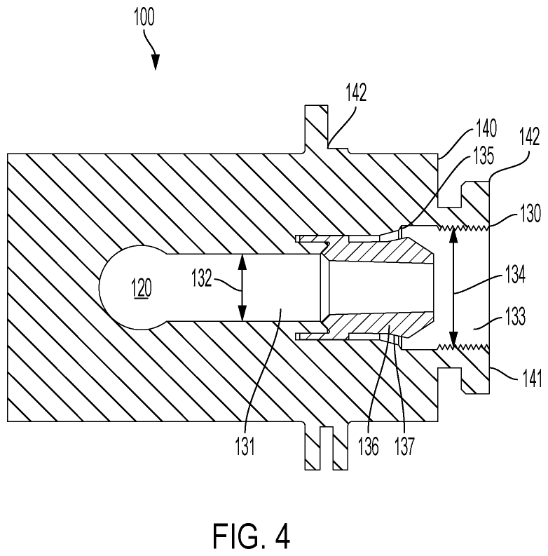

FIG. 3 illustrates a side cross section view of an exemplary embodiment of a manifold (100) for a fluid distribution device ((10) as shown in FIG. 2). As shown in FIG. 3, the intake port (110) is fluidly connected to an interior space ((120) as shown in FIG. 4) within the manifold. The interior space being downstream of the intake port such that fluid—from a tank, spigot, or other source external to the fluid distribution device—may flow through the intake port into the interior space. The fluid then flows into and through the plurality of recessed outlet ports (130) which are downstream of the interior space for discharge to the plurality of tubes ((200) as shown in FIG. 2).

FIG. 4 illustrates an end cross section view of an exemplary embodiment of a manifold (100) for a fluid distribution device ((10) as shown in FIG. 2). In FIG. 4, additional details of an exemplary embodiment of a recessed outlet port (130) are visible. As shown in FIG. 4, the recessed outlet port includes a primary hole (131), a threaded secondary hole (133), and a sleeve (136) which may be manufactured integrally with the manifold or may be a separable insert which is placed into the recessed outlet port.

The primary hole (131) extends through a manifold sidewall (140) and may therefore be considered a through hole which allows fluid to flow from the interior space (120) into and through the recessed outlet port. As illustrated in FIG. 4, the primary hole will have a primary hole diameter (132).

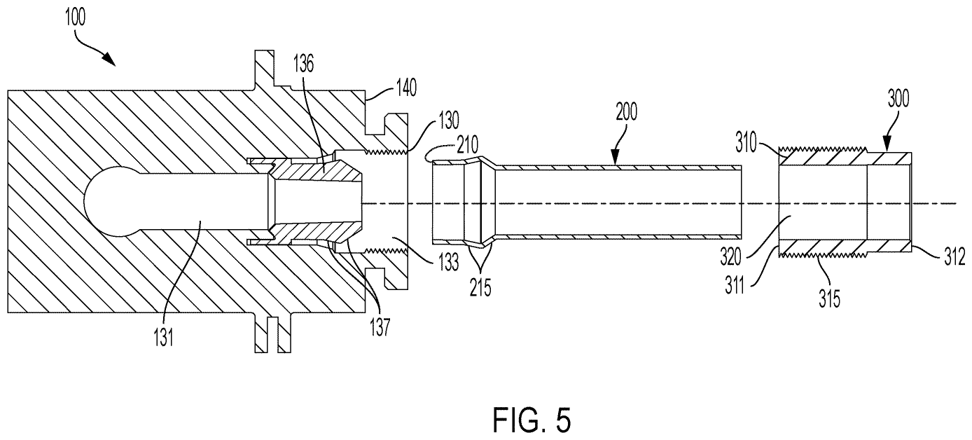

The threaded secondary hole (133) may originate from a manifold sidewall outer surface (141), but will not extend through the manifold sidewall. As such, the threaded secondary hole will have a secondary hole depth which is less than a manifold sidewall thickness (142) resulting in a secondary hole lip (135) being a flat surface against which a fitting ((300) as shown in FIG. 5)—threaded into the threaded secondary hole as described herein—may be disposed when fully tightened. As illustrated in FIG. 4, the threaded secondary hole will have a secondary hole diameter (134) which is greater than the primary hole diameter (132). The internal facing surface of the secondary hole will be threaded to mate with a threaded outer surface ((315) as shown in FIG. 5) of a fitting of the plurality of fittings.

The sleeve (136) extends from the secondary hole lip (135) and includes a sleeve bulbous region (137). The sleeve bulbous region being configured to mate with a tube bulbous region ((215) as shown in FIG. 5) of a tube ((200) as shown in FIG. 5) of the plurality of tubes.

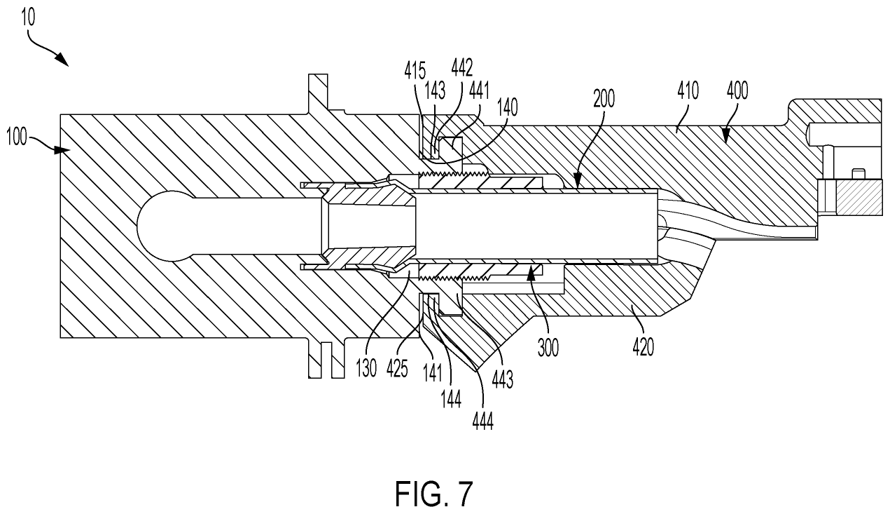

FIG. 5 illustrates an exploded end cross section view of an exemplary embodiment of a manifold (100), tube (200), and fitting (300) for a fluid distribution device ((10) as shown in FIG. 2). As shown in FIG. 5, the tube may include a first end (210) having a tube bulbous region (215). This tube bulbous region is configured to extend over and around the sleeve bulbous region (137) to connect the tube to the recessed outlet port (130) as illustrated in FIG. 7.

As further illustrated in FIG. 5, the fitting (300) includes a fitting sidewall (310), a through hole (320), and a threaded outer surface (315). The through hole extending from a fitting first end (311) through a fitting second end (312). Preferably, the through hole will have an inner diameter which is slightly greater than an outer diameter of the tube (200) such that the tube may extend into and through the through hole.

The threaded outer surface (315) of the fitting (300) may originate from the fitting first end (311), but preferably does not extend to the fitting second end (312). Preferably, a gripping surface—such as a hex or spline adapted to fit a wrench-will originate from the fitting second end (312) and will extend to the terminal portion of the threaded outer surface. The threaded outer surface mates with the threaded secondary hole (133) in the manifold sidewall outer surface ((141) as shown in FIG. 4) to connect the fitting to the manifold (100). As the fitting is advanced into the threaded secondary hole, the fitting first end applies pressure against the mated bulbous regions of the sleeve (136) and the tube to form a secure, fluid tight seal between the tube and the sleeve, and between a manifold interface near the primary hole (131). Prior to inserting the tube (200) onto the sleeve (136), the portion of the tube at or near the first end (210) may be heated to the point that the tube material may deform allowing the tube to extend over the sleeve bulbous region (137). In doing so, the sidewall thickness of the tube in the heated region may be reduced relative to its preheated size.

Each tube of the plurality of tubes (200) will have a sidewall thickness. Preferably, the sidewall thickness will be in a range of between 0.035 cm and 0.065 cm, but may also be in a range selected from the group consisting of between 0.035 cm and 0.055 cm, between 0.035 cm and 0.045 cm, between 0.045 cm and 0.065 cm, between 0.045 cm and 0.055 cm, and between 0.055 cm and 0.065 cm.

In some embodiments, particularly where the fluid distribution and containment system is highly insulated, where friction between fluid and moving components (e.g.—pump impeller) with high flow velocities can drive high rates of contact and separation between fluid and conduit walls producing charge generation, and/or where the fluid being distributed is nonconductive, it may be beneficial to manufacture the plurality of tubes of a conductive material to mitigate the effects of electrostatic discharge. Material conductivity may be measured by volume resistivity, surface resistivity, or both. Preferably, the volume resistivity of the conductive material will be in a range of between 2.0×10² Ω.cm and 8.0×10² Ω.cm, but may also be in a range of between 2.0×10² Ω.cm and 6.0×10² Ω.cm, between 2.0×10² Ω.cm and 4.0×10² Ω.cm, between 4.0×10² Ω.cm and 8.0×10² Ω.cm, between 4.0×10² Ω.cm and 6.0×10² Ω.cm, and between 6.0×10² Ω.cm and 8.0×10² Ω.cm. Preferably, the surface resistivity will be in a range of between 10⁵ Ω/sq and 10² Ω/sq. One non-limiting example of such a conductive material is a conductive or doped virgin-grade perfluoroalkoxy alkane (PFA) material such as FluoroLine® available from Entegri, Inc. of Billerica, Massachusetts, U.S.A.

While the Figures illustrate an embodiment of a fluid distribution device having three recessed outlet ports (130) corresponding to three tubes (200) and three fittings (300), other embodiments may exist. In general, the plurality of recessed outlet ports may include a number of recessed outlet ports which is an integer in the range of between 2 and 10. Similarly, the plurality of tubes may include a number of tubes which is an integer in the range of between 2 and 10. Likewise, the plurality of fittings may include a number of fittings which is an integer in the range of between 2 and 10. Preferably, the number of recessed outlet ports will equal the number of tubes, and the number of tubes will equal the number of fittings.

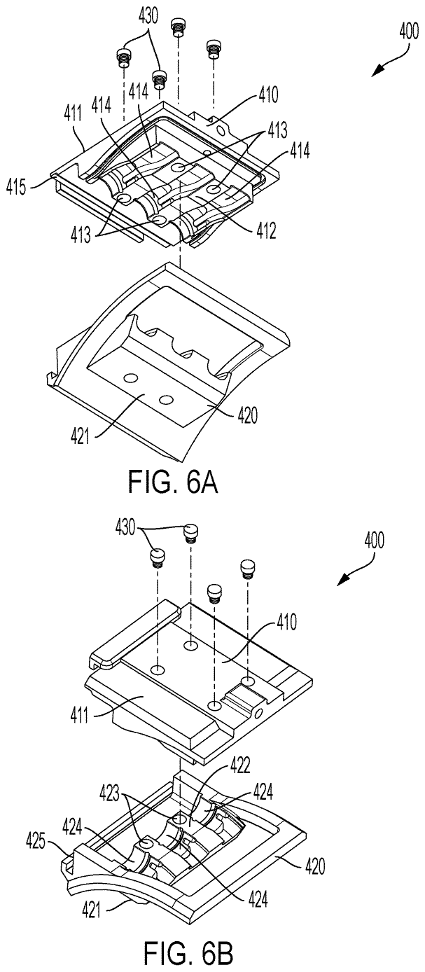

FIGS. 6A and 6B illustrate an exemplary embodiment of a support block (400) for a fluid distribution device ((10) as shown in FIG. 2). The support block-when present—may include an upper section (410), a lower section (420), a plurality of fasteners (430), and an attachment mechanism (440). When assembled, the support block provides surfaces against which a portion of the tubes ((200) as shown in FIG. 2) and fittings ((300) as shown in FIG. 2) may abut to prevent or reduce the likelihood of the fittings unthreading from their recessed outlet ports ((130) as shown in FIG. 1) and to reduce or prevent wear on the tubes caused by vibrations, sagging, or the like.

As illustrated in FIG. 6A, the upper section (410) may include an upper section outer surface (411) and an upper section inner surface (412) opposite the upper section outer surface. As used herein, the terms “outer surface” and “inner surface” are relative to the position of the tubes ((200) as shown in FIG. 7) and fittings ((300) as shown in FIG. 7) when the fluid distribution device ((10) as shown in FIG. 7) is assembled with “outer surface” referring to the surface facing opposite the tubes and fittings and “inner surface” referring to the surface facing towards the tubes and fittings.

The upper section inner surface (412) may include a plurality of upper section grooves (414). When present, each upper section groove of the plurality of upper section grooves may be configured—i.e., sized and shaped—to a first longitudinal portion of an exterior profile of one tube and one fitting of the plurality of tubes ((200) as shown in FIG. 7) and the plurality of fittings ((300) as shown in FIG. 7). Doing so—in combination with the lower section grooves ((424) illustrated in FIG. 6B)—allows the upper section (410) of the support block (400) to fit around a portion of the tubes and fittings to assist in preventing unthreading from the outlet ports ((130) as shown in FIG. 1) and to reduce or prevent wear on the tubes caused by vibrations, sagging, or the like.

As illustrated in FIG. 6B, the lower section (420) may include a lower section outer surface (421) and a lower section inner surface (422) opposite the lower section outer surface. As used herein, the terms “outer surface” and “inner surface” are relative to the position of the tubes ((200) as shown in FIG. 7) and fittings ((300) as shown in FIG. 7) when the fluid distribution device ((10) as shown in FIG. 7) is assembled with “outer surface” referring to the surface facing opposite the tubes and fittings and “inner surface” referring to the surface facing towards the tubes and fittings.

The lower section inner surface (422) may include a plurality of lower section grooves (424). When present, each lower section groove of the plurality of lower section grooves may be configured—i.e.—sized and shaped—to a second longitudinal portion of an exterior profile of one tube and one fitting of the plurality of tubes ((200) as shown in FIG. 7) and the plurality of fittings ((300 as shown in FIG. 7). Doing so—in combination with the upper section grooves ((414) illustrated in FIG. 6A)—allows the lower section (420) of the support block (400) to fit around a portion of the tubes and fittings to assist in preventing unthreading from the outlet ports ((130) as shown in FIG. 1) and to reduce or prevent wear on the tubes caused by vibrations, sagging, or the like.

When the fluid distribution device ((10) as shown in FIG. 2) is assembled, it is preferred that the upper section (410) of the support block (400) be securely connected to the lower section (420) of the support block. Doing so may involve the use of any number of different types of fasteners (430) such as bolts, screws, rivets, clamps, clips, and combinations thereof. One such embodiment is illustrated in FIGS. 6A and 6B in which the fasteners are in the form of bolts. In such an embodiment, the upper section may include a plurality of upper section through holes (413) extending from the upper section outer surface (411) through the upper section inner surface (412). The lower section may include a plurality of lower section holes (423) extending into the lower section inner surface (422) with each lower section hole corresponding to a size and location of one of the upper section through holes. Preferably, the lower section holes will be threaded such that a bolt passing through an upper section through hole may be threaded into the lower section hole to securely connect the upper section to the lower section.

FIG. 7 illustrates an end cross section view of an exemplary embodiment of a fluid distribution device (10) which is fully assembled. In FIG. 7, details of an exemplary embodiment of an attachment mechanism (440) for connecting the support block (400) to the manifold sidewall outer surface (141) are shown. In the embodiment shown in FIG. 7, the attachment mechanism includes a first lip (441) extending along at least a portion of a manifold sidewall upper edge (143) and a second lip (443) extending along at least a portion of a manifold sidewall lower edge (144). Correspondingly, an upper section proximal edge (415) of the upper section (410) of the support block (400) includes a first tab (442) while a lower section proximal edge (425) of the lower section (420) of the support block includes a second tab (444). When assembled, the first lip is configured to mate with the first tab and the second lip is configured to mate with the second tab such that-as the upper section and lower section of the support block are secured to one another via the fastener (430)—the lips and tabs secure the support block to the manifold sidewall outer surface.

While FIG. 7 illustrates an exemplary embodiment of an attachment mechanism (440) comprising lips and tabs, other attachment mechanisms for securing the support block (400) to the manifold sidewall outer surface (141) are envisioned. Such embodiments may include the use of one or more fasteners—such as bolts, screws, rivets, clamps, clips, or the like.

The various components of the fluid distribution device described herein—in particular the support block—may be manufactured of any number of rigid materials such as rigid polymers, metals, and the like. Rigid polymer materials are preferred with polyether ether ketone (PEEK) being one preferred rigid polymer material. In some embodiments, the polymer material—in particular PEEK material—may be reinforced with glass fibers. Other rigid polymer materials—particularly those used to form the manifold, tubes, and fittings—may include polytetrafluoroethylene (PTFE), perfluoroalkoxy alkane (PFA), and polyvinylidene fluoride (PVDF). Alternatively, metal materials such as aluminum—which may be coated with nickel—may be used to form one or more of the components. In some embodiments, the rigid material (such as an Al sleeve, core) may be coated to reduce or prevent oxidation. Non-limiting examples of coating materials may include polyvinylidene fluoride (PVDF), ethylene chlorotrifluoroethylene (ECTFE), perfluoroalkoxy alkane (PFA), fluorinated ethylene propylene (FEP), ethylene tetrafluoroethylene (ETFE), and nickel polytetrafluoroethylene (Ni-PTFE).

The embodiments of a fluid distribution device described herein have been shown to reduce or eliminate leakage—in particular when used for distributing isopropyl alcohol (IPA) used in semiconductor manufacturing processes. The recessed outlet port and fitting configuration, including the sleeve and tube having bulbous regions has been shown to reduce or eliminate leakage at the manifold and fittings. Additionally, connecting the support block to the manifold sidewall has been shown to reduce or eliminate leakage by supporting the fitting and tube assemblies without applying unwanted pressure along the length thereof which can result in wear on the fittings and tubes. The reduced or eliminated leakage has been observed where the invented fluid distribution device can withstand more than 2,000 cycles with less than 0.3 % pressure drop after twenty (20) minutes of operation where prior fluid distribution device achieved between 3.0 and 10 % pressure drop under the same conditions which indicates leakage.

While the fluid distribution device has been described as having one or more exemplary designs, the present device may be further modified within the spirit and scope of this disclosure. This application is therefore intended to cover any variations, uses, or adaptations of the device using their general principles.

What is claimed is:

1. A fluid distribution device (10), comprising:
a manifold (100) having an intake port (110), an interior space (120) downstream of the intake port, and a plurality of recessed outlet ports (130) downstream of the interior space wherein each recessed outlet port of the plurality of recessed outlet ports includes:
a primary hole (131) extending through a manifold sidewall (140), said primary hole having a primary hole diameter (132);
a threaded secondary hole (133) originating from a manifold sidewall outer surface (141), said secondary hole having a depth which is less than a manifold sidewall thickness (142), a secondary hole diameter (134) which is greater than the primary hole diameter, and a secondary hole lip (135);
a sleeve (136) extending from the secondary hole lip, said sleeve having a sleeve bulbous region (137);
a plurality of tubes (200) with each tube of the plurality of tubes having a first end (210) comprising a tube bulbous region (215) configured to mate with the sleeve bulbous region;
a plurality of fittings (300) with each fitting of the plurality of fittings configured to connect a tube of the plurality of tubes to a recessed outlet port of the plurality of recessed outlet ports, each fitting of the plurality of fittings comprising:
a fitting sidewall (310);
a through hole (320) extending from a fitting first end (311) through a fitting second end (312); and
a threaded outer surface (315) originating from the fitting first end and terminating before the fitting second end, said threaded outer surface configured to mate with the threaded secondary hole; and
a support block (400) comprising:
an upper section (410) having an upper section outer surface (411), an upper section inner surface (412) opposite the upper section outer surface, and a plurality of upper section grooves (414) in the upper section inner surface with each upper section groove of the plurality of upper section grooves configured to a first longitudinal portion of an exterior profile of one tube and one fitting of the plurality of tubes and the plurality of fittings;
a lower section (420) having a lower section outer surface (421), a lower section inner surface (422) opposite the lower section outer surface, and a plurality of lower section grooves (424) in the lower section inner surface with each lower section groove of the plurality of lower section grooves configured to a second longitudinal portion of an exterior profile of one tube and one fitting of the plurality of tubes and the plurality of fittings;
at least one fastener (430) configured to securely connect the upper section to the lower section; and
an attachment mechanism (440) configured to connect the support block to the manifold sidewall outer surface.

2. The fluid distribution device of claim 1, wherein the plurality of recessed outlet ports includes a number of recessed outlet ports which is an integer in the range of between 2 and 10.

3. The fluid distribution device of claim 2, wherein the plurality of tubes includes a number of tubes which is an integer in the range of between 2 and 10, and the number of recessed outlet ports equals the number of tubes.

4. The fluid distribution device of claim 3, wherein the plurality of fittings includes a number of fittings which is an integer in the range of between 2 and 10, and the number of tubes equals the number of fittings.

5. The fluid distribution device of claim 1, wherein the upper section comprises a plurality of upper section through holes (413) extending from the upper section outer surface through the upper section inner surface, the lower section comprises a plurality of lower section holes (423) extending into the lower section inner surface, and the fastener comprises a plurality of bolts with each bolt configured to securely connect the upper section to the lower section by passing through one upper section through hole of the plurality of upper section through holes and threading into one lower section hole of the plurality of lower section holes.

6. The fluid distribution device of claim 1, wherein the attachment mechanism comprises:
a first lip (441) extending along at least a portion of a manifold sidewall upper edge (143) and configured to mate with a first tab (442) extending from an upper section proximal edge (415); and
a second lip (443) extending along at least a portion of a manifold sidewall lower edge (144) and configured to mate with a second tab extending from a lower section proximal edge (425).

7. The fluid distribution device of claim 1, wherein each tube of the plurality of tubes has a sidewall thickness in a range of between 0.035 cm and 0.065 cm.

8. The fluid distribution device of claim 1, wherein each tube of the plurality of tubes is manufactured of a conductive material having a volume resistivity in a range of between 2.0×10² Ω.cm and 8.0×10² Ω.cm.

9. The fluid distribution device of claim 1, wherein each tube of the plurality of tubes is manufactured of a conductive material having a surface resistivity in a range of between 10⁵ Ω/sq and 10⁶ Ω/sq.

10. The fluid distribution device of claim 1, wherein each tube of the plurality of tubes is manufactured of perfluoroalkoxy alkane (PFA).

11. The fluid distribution device of claim 1, wherein the fluid distribution device is void of o rings in a fluid path extending between the intake port and each tube of the plurality of tubes.

12. The fluid distribution device of claim 1, wherein the manifold, the plurality of tubes, and the plurality of fittings are each manufactured of a polymer material.

13. The fluid distribution device of claim 12, wherein the polymer material is selected from the group consisting of polytetrafluoroethylene (PTFE), perfluoroalkoxy alkane (PFA), and polyvinylidene fluoride (PVDF).

14. The fluid distribution device of claim 12, wherein the polymer material is reinforced with glass fibers.

15. The fluid distribution device of claim 12, wherein the polymer material is coated with a material selected from the group consisting of polyvinylidene fluoride (PVDF), ethylene chlorotrifluoroethylene (ECTFE), perfluoroalkoxy alkane (PFA), fluorinated ethylene propylene (FEP), ethylene tetrafluoroethylene (ETFE), and nickel polytetrafluoroethylene (Ni-PTFE).

16. The fluid distribution device of claim 1, wherein the support block is manufactured of a material selected from the group consisting of a metal material and a polymer material.

17. The fluid distribution device of claim 16, wherein the support block is manufactured of a polymer material.

18. The fluid distribution device of claim 17, wherein the polymer material is polyether ether ketone (PEEK).

19. The fluid distribution device of claim 18, wherein the polymer material is reinforced with glass fibers.

20. The fluid distribution device of claim 16, wherein the polymer material is coated with a material selected from the group consisting of polyvinylidene fluoride (PVDF), ethylene chlorotrifluoroethylene (ECTFE), perfluoroalkoxy alkane (PFA), fluorinated ethylene propylene (FEP), ethylene tetrafluoroethylene (ETFE), and nickel polytetrafluoroethylene (Ni-PTFE).
